(19) United States
(12) Patent Application Publication
(10) Pub. No.: US 2026/0156992 A1
(43) Pub. Date: Jun. 4, 2026

(54) STAMP, METHOD FOR MANUFACTURING THE SAME, TRANSFER DEVICE, AND MASS TRANSFER METHOD

(71) Applicants: Beijing BOE Technology Development Co., Ltd., Beijing (CN); BOE TECHNOLOGY GROUP CO., LTD., Beijing (CN)

(72) Inventors: Miaomiao JIA, Beijing (CN); Menghua ZHAO, Beijing (CN); Shulei LI, Beijing (CN); Ying ZHOU, Beijing (CN); Xinhua LIU, Beijing (CN); Zhao KANG, Beijing (CN); Hua HUANG, Beijing (CN)

(21) Appl. No.: 18/705,565

(22) PCT Filed: Aug. 30, 2023
(86) PCT No.: PCT/CN2023/115707

§ 371 Date: Apr. 28, 2024

(51) Int. Cl. H10H 29/03

(52) U.S. Cl. CPC H10H 29/03

(57) ABSTRACT

A stamp includes: a substrate; anti-tilting structures located on a side of the substrate and spaced apart from each other; and transfer structures located on the side of the substrate and spaced apart from each other. Each transfer structure has therein at least one hole, and each hole has at least a first opening at a first surface, which is distal to the substrate, of a corresponding transfer structure. The anti-tilting structures are in one-to-one correspondence with the transfer structures. The anti-tilting structures surround peripheries of the respective transfer structures, and orthogonal projections of the anti-tilting structures on the substrate do not overlap with orthogonal projections of the respective transfer structures on the substrate. An end surface, which is distal to the substrate, of each anti-tilting structure is not lower than an end surface, which is distal to the substrate, of a corresponding transfer structure.

### CROSS-REFERENCE TO RELATED APPLICATIONS

This is a National Phase Application filed under 35 U.S.C. 371 as a national stage of PCT/CN2023/115707 filed on Aug. 30, 2023, the entire content of which is incorporated herein by reference.

### TECHNICAL FIELD

Embodiments of the present disclosure relate to the field of display technology, and in particular, relate to a stamp, a method for manufacturing the same, a transfer device, and a mass transfer method (which may also be referred to as “massive transfer method” or “enormous-amount transfer method”).

### BACKGROUND

A micro light emitting diode (micro LED) has characteristics such as not requiring backlight, self-luminescence, and the like, and has advantages such as simple structure, very long service lifetime, high luminance (or brightness), low power consumption, super high resolution, and the like as compared with a liquid crystal display (LCD) and an organic light emitting diode (OLED) product, thereby having promising application prospect.

### SUMMARY

In a first aspect, embodiments of the present disclosure provide a stamp, which includes a substrate;
a plurality of anti-tilting structures, which are located on a side of the substrate and are spaced apart from each other; and
a plurality of transfer structures, which are located on the side of the substrate where the anti-tilting structures are located and are spaced apart from each other, wherein
each transfer structure has therein at least one hole, and each hole has at least a first opening at a first surface, which is distal to the substrate, of a corresponding transfer structure;
the plurality of anti-tilting structures are in one-to-one correspondence with the plurality of transfer structures;
the plurality of anti-tilting structures surround peripheries of the respective transfer structures, and orthogonal projections of the plurality of anti-tilting structures on the substrate do not overlap with orthogonal projections of the respective transfer structures on the substrate; and
a distance between an end surface, which is distal to the substrate, of each anti-tilting structure and the substrate is greater than or equal to a distance between an end surface, which is distal to the substrate, of a corresponding transfer structure and the substrate.

In some embodiments, each hole penetrates through a thickness of a corresponding transfer structure.

In some embodiments, each hole is a blind hole formed in a corresponding transfer structure.

In some embodiments, a light emitting diode has a second surface in contact with the first surface of a corresponding transfer structure, and an orthogonal projection of the second surface on the substrate falls within an orthogonal projection of the first surface on the substrate;
the at least one hole includes one hole;
in any direction parallel to the first surface, a size of the first surface is greater than a size of the second surface, and the size of the second surface is greater than a size of the first opening; and
½ of a difference between the size of the first surface and the size of the first opening is greater than an alignment accuracy of an alignment device for aligning and attaching the light emitting diode to the corresponding transfer structure.

In some embodiments, the first surface of the transfer structure includes a central region and a peripheral region surrounding the central region; and
the at least one hole includes a plurality of holes, and first openings of the plurality of holes are uniformly distributed in the central region.

In some embodiments, a light emitting diode has a second surface in contact with the first surface of the corresponding transfer structure, and an orthogonal projection of the second surface on the substrate falls within an orthogonal projection of the first surface on the substrate;

in any direction parallel to the first surface, a size of the first surface is greater than a size of the second surface, and the size of the second surface is greater than a size of the central region; and
½ of a difference between the size of the first surface and the size of the central region is greater than an alignment accuracy of an alignment device for aligning and attaching the light emitting diode to the corresponding transfer structure.

In some embodiments, the first surface of each transfer structure is configured to contact and attach to a second surface of a light emitting diode, and a distance between an end surface of each anti-tilting structure distal to the substrate and the substrate is less than a distance between an end surface of the light emitting diode distal to the substrate and the substrate.

In some embodiments, a shape of the orthogonal projection of each anti-tilting structure on the substrate is a ring; and
shapes of the orthogonal projections of the transfer structures on the substrate abut on shapes of the orthogonal projections of the respective anti-tilting structures on the substrate.

In some embodiments, the shape of the orthogonal projection of each transfer structure on the substrate includes a circle, a rectangle, a triangle, or a polygon.

In some embodiments, a shape of an orthogonal projection of each first opening on the substrate includes a circle, a rectangle, a triangle, or a polygon.

In some embodiments, a shape of a section, which is perpendicular to the substrate, of each hole includes a rectangle, a trapezoid, or an inverted trapezoid.

In some embodiments, the plurality of transfer structures are arranged to be equally spaced apart from each other in an array; and
the shapes of the orthogonal projections of the plurality of transfer structures on the substrate are identical to each other, and the shapes of the orthogonal projections of any two adjacent columns of transfer structures on the substrate have different orientations; or, the shapes of the orthogonal projections of some of the plurality of transfer structures on the substrate are different from the shapes of the orthogonal projections of others of the plurality of transfer structures on the substrate.

In some embodiments, some of the plurality of transfer structures are arranged in an array to be spaced apart from each other by a first distance, and others of the plurality of transfer structures are arranged in an array to be spaced apart from each other by a second distance, where the first distance is greater than the second distance.

In some embodiments, each transfer structure is made of an elastic resin material, and
the elastic resin material includes any one of polymethyl methacrylate, propylene glycol methyl ether acetate, silicon resin, or acrylic resin.

In some embodiments, a material of each anti-tilting structure includes any one of silicon oxide, silicon nitride, silicon oxynitride, copper, aluminum, molybdenum, or silver.

In some embodiments, each transfer structure has a height in a range of 4 μm to 15 μm.

In some embodiments, a linewidth of the ring of each anti-tilting structure is in a range of 2 μm to 30 μm.

In a second aspect, embodiments of the present disclosure further provide a transfer device, which includes the stamp according to any one of the foregoing embodiments.

In a third aspect, embodiments of the present disclosure further provide a method for manufacturing a stamp, the method including:
forming a plurality of anti-tilting structures on a side of a substrate by a patterning process; and
forming a plurality of transfer structures on the side of the substrate where the above step is completed by a patterning process, to form the plurality of transfer structures and the plurality of anti-tilting structures on the same side of the substrate;
wherein the forming a plurality of transfer structures includes simultaneously forming a pattern of the transfer structures and a pattern of a hole in each of the transfer structures.

In some embodiments, the forming a plurality of anti-tilting structures on a side of a substrate by a patterning process includes:
depositing an anti-tilting structure film on the side of the substrate;
coating a photoresist layer on a side of the anti-tilting structure film distal to the substrate;
exposing the photoresist layer by using a mask including a pattern of the anti-tilting structures;
developing to remove photoresist in exposed regions of the photoresist layer;
etching and removing portions of the anti-tilting structure film which are not covered by the photoresist by a dry etching process or a wet etching process to form the pattern of the plurality of anti-tilting structures; and
stripping off residual photoresist.

In some embodiments, the forming a plurality of transfer structures on the side of the substrate where the above step is completed by a patterning process includes:
coating a layer of organic resin material on the side of the substrate;
exposing the layer of organic resin material by using a mask including a pattern of the transfer structures; and
developing to remove the organic resin material in exposed regions of the layer of organic resin material to form the pattern of the plurality of transfer structures.

In a fourth aspect, embodiments of the present disclosure provide a mass transfer method, including:
aligning and combining a stamp with a transfer substrate carrying a plurality of light emitting diodes in a process chamber in a first vacuum environment, and then restoring the process chamber to the atmospheric environment, thereby picking up the light emitting diodes by the stamp, wherein an air pressure in the first vacuum environment is less than an air pressure in the atmospheric environment, a plurality of transfer structures of the stamp are in one-to-one correspondence with at least some of the plurality of light emitting diodes, and second surfaces of the light emitting diodes cover first openings at first surfaces of respective transfer structures, such that holes in the transfer structures form sealed cavities; and
transferring, by the stamp, the picked up light emitting diodes to a driving substrate in the process chamber in the atmospheric environment, bonding a first connecting terminal of each light emitting diode to a second connecting terminal of the driving substrate, and then vacuumizing the process chamber to a second vacuum environment, thereby releasing the light emitting diodes by the stamp, wherein an air pressure in the second vacuum environment is less than the air pressure in the first vacuum environment.

In some embodiments, the aligning and combining a stamp with a transfer substrate carrying a plurality of light emitting diodes in a process chamber in a first vacuum environment, and then restoring the process chamber to the atmospheric environment, thereby picking up the light emitting diodes by the stamp include:
aligning and pressing the stamp and the transfer substrate together in the process chamber in the first vacuum environment;
restoring the process chamber to the atmospheric environment to form a negative pressure in each sealed cavity;
dissociating an adhesive layer for fixing the light emitting diodes on the transfer substrate by means of laser dissociation; and
separating dissociated transfer substrate from the stamp, thereby transferring the light emitting diodes to the stamp.

In some embodiments, the transferring, by the stamp, the picked up light emitting diodes to a driving substrate in the process chamber in the atmospheric environment, bonding a first connecting terminal of each light emitting diode to a second connecting terminal of the driving substrate, and then vacuumizing the process chamber to a second vacuum environment, thereby releasing the light emitting diodes by the stamp include:
aligning and attaching the stamp carrying the light emitting diodes to the driving substrate in the process chamber in the atmospheric environment, to bond the first connecting terminal of each light emitting diode to a corresponding second connecting terminal of the driving substrate;
applying a pressure to the stamp, and heating the driving substrate, to complete bonding of the first connecting terminal to the corresponding second connecting terminal;
vacuumizing the process chamber to the second vacuum environment to form a positive pressure in each sealed cavity; and
separating the stamp from the light emitting diodes to transfer the light emitting diodes to the driving substrate.

In some embodiments, the applying a pressure to the stamp includes:
mechanically pressurizing; or
gaseously pressurizing.

### BRIEF DESCRIPTION OF THE DRAWINGS

The drawings, which are included to provide further understanding of the embodiments of the present disclosure and constitute a part of this specification, illustrate the present disclosure together with the embodiments of the present disclosure, but are not intended to limit the present disclosure. The above and other features and advantages will become more apparent to one of ordinary skill in the art by describing in detail exemplary embodiments of the present disclosure with reference to the drawings, in which:

FIG. 1a is a schematic diagram illustrating a transfer process and a transfer principle for a van der Waals force type stamp;

FIG. 1b is a schematic diagram illustrating a relationship between an energy release speed and a peeling off speed during the process of picking up and releasing by using a van der Waals force type stamp;

FIG. 1c is a schematic cross-sectional view illustrating a structure of a PDMS stamp;

FIG. 1d is a schematic diagram illustrating an application of a PDMS stamp in large-size multiple mass transfers;

FIG. 1e is a schematic diagram illustrating an application of a PDMS stamp in transferring of a small-size array;

FIG. 2a is a schematic top view illustrating a structure of a stamp according to an embodiment of the present disclosure;

FIG. 2b is a schematic cross-sectional view illustrating a structure of the stamp shown in FIG. 2a taken along a cutting line AA′;

FIG. 2c is a schematic cross-sectional view illustrating another structure of the stamp shown in FIG. 2a taken along the cutting line AA′;

FIG. 2d is a schematic top view illustrating a dimensional relationship among a first surface of a transfer structure of a stamp according to an embodiment of the present disclosure, a first opening of the transfer structure, and a second surface of a light emitting diode;

FIG. 2e is a schematic cross-sectional view illustrating a dimensional relationship among a first surface of a transfer structure of a stamp according to an embodiment of the present disclosure, a first opening of the transfer structure, and a second surface of a light emitting diode;

FIG. 2f is a schematic top view illustrating another dimensional relationship among a first surface of a transfer structure of a stamp according to an embodiment of the present disclosure, a first opening of the transfer structure, and a second surface of a light emitting diode;

FIG. 2g is a schematic structural cross-sectional view illustrating that a transfer structure of a stamp according to an embodiment of the present disclosure adsorbs (or sticks to) a light emitting diode;

FIG. 2h is a schematic top view illustrating a structure of another stamp according to an embodiment of the present disclosure;

FIG. 2i is a schematic top view illustrating a structure of another stamp according to an embodiment of the present disclosure;

FIG. 2j is a schematic cross-sectional view illustrating another structure of the stamp shown in FIG. 2a taken along the cutting line AA′;

FIG. 2k is a schematic cross-sectional view illustrating another structure of the stamp shown in FIG. 2a taken along the cutting line AA′;

FIG. 2l is a schematic top view illustrating a structure of another stamp according to an embodiment of the present disclosure;

FIG. 2m is a schematic top view illustrating a structure of another stamp according to an embodiment of the present disclosure;

FIG. 2n is a schematic top view illustrating a structure of another stamp according to an embodiment of the present disclosure;

FIG. 3 is a flowchart of a method for manufacturing a stamp according to an embodiment of the present disclosure;

FIG. 4a is a flowchart of a mass transfer method according to an embodiment of the present disclosure;

FIG. 4b is a schematic diagram illustrating a process of picking up light emitting diodes from a transfer substrate by a stamp according to an embodiment of the present disclosure; and

FIG. 4c is a schematic diagram illustrating a process of transferring and releasing light emitting diodes to a driving substrate by a stamp according to an embodiment of the present disclosure.

### DETAILED DESCRIPTION OF EMBODIMENTS

To make one of ordinary skill in the art better understand technical solutions of the embodiments of the present disclosure, a stamp, a method for manufacturing a stamp, a transfer device, and a mass transfer method provided by the present disclosure will be described below in detail with reference to the accompanying drawings and exemplary embodiments.

The embodiments of the present disclosure will be described more fully hereinafter with reference to the accompanying drawings, but the embodiments shown may be embodied in different forms and should not be construed as limited to the forms set forth herein. Rather, these embodiments are provided such that the present disclosure will be thorough and complete, and will fully convey the scope of the present disclosure to one of ordinary skill in the art.

Embodiments of the present disclosure are not limited to the embodiments shown in the drawings, but include modifications of configurations formed based on a manufacturing process. Thus, the regions illustrated in the figures are exemplary, and the shapes of the regions shown in the figures illustrate exemplary shapes of the regions but are not intended to be limiting.

Mass production of micro LEDs still faces many difficulties, among which technical bottlenecks are mass transfer of the micro LEDs and mass bonding of the micro LEDs. The mass transfer of the micro LEDs includes technologies of electrostatic adsorption transfer, stamp transfer, magnetic adsorption transfer, and the like. At present, the most adopted transfer method is a transfer by the van der Waals force type stamp (which may be made of polydimethylsiloxane (PDMS)), and the most adopted bonding method is eutectic bonding.

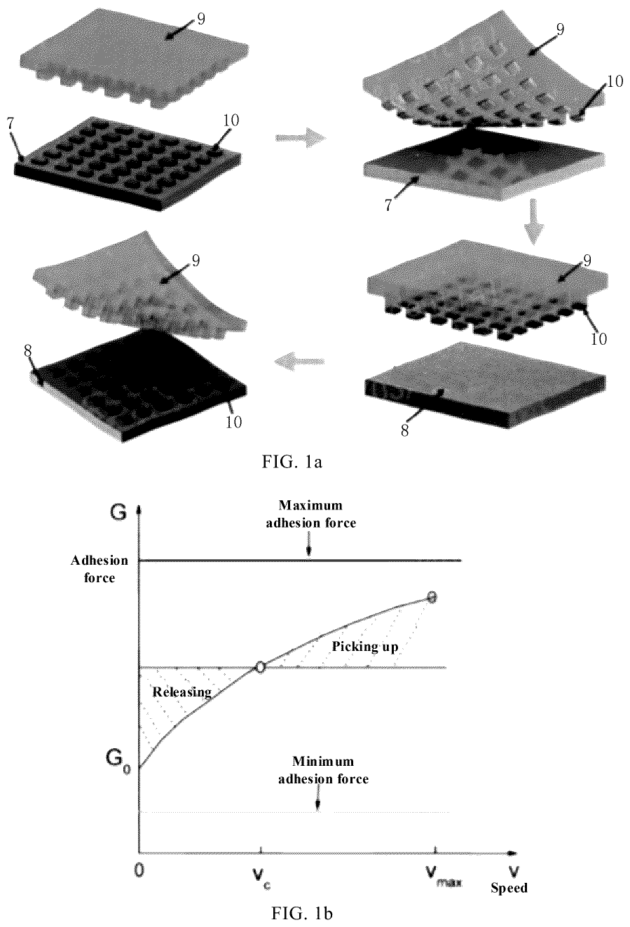

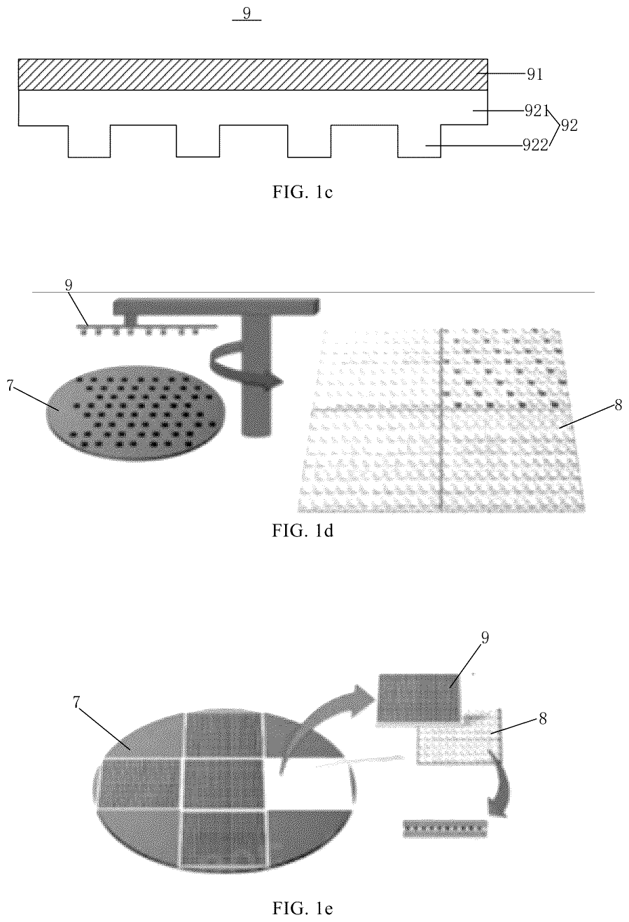

The principle and the process flow for the transfer by the van der Waals force type stamp are shown in FIGS. 1a, 1b, and 1c. A PDMS stamp has certain viscosity, and an adhesion of the PDMS stamp to micro LEDs may be adjusted through a speed of lifting up the PDMS stamp. An interface adhesion of the PDMS stamp to the micro LEDs is large when the PDMS stamp is lifted up quickly, thereby picking up the micro LEDs, whereas the interface adhesion of the PDMS stamp to the micro LEDs is small (i.e., the adhesion <a bonding force between a connecting terminal of a micro LED and a connecting terminal of a driving substrate) when the PDMS stamp is lifted up slowly, thereby separating the micro LEDs from the PDMS stamp.

Referring to FIG. 1a which is a schematic diagram illustrating a transfer process and a transfer principle for a van der Waals force type stamp, and FIG. 1b which is a schematic diagram illustrating a relationship between an energy release speed and a peeling off speed during the process of picking up and releasing by using the van der Waals force type stamp, an elastomeric PDMS stamp 9 is aligned with micro LED devices 10 on a transfer substrate 7, and is pressed down quickly; the PDMS stamp 9 is deformed and is tightly attached to the micro LED devices 10; the PDMS stamp 9 is rapidly lifted up, thereby pulling up the micro LED devices 10; the PDMS stamp 9 carrying the micro LED devices 10 is aligned with a driving substrate 8 and is quickly pressed down; the PDMS stamp 9 is slightly shifted to one side, and is slowly lifted up; then the deformation of the PDMS stamp 9 disappears, resulting in the separation of the PDMS stamp 9 from the micro LED devices 10, such that the micro LED devices 10 are transferred (or are transfer printed).

Referring to FIG. 1c which is a schematic cross-sectional view illustrating a structure of a PDMS stamp, the PDMS stamp 9 includes a glass substrate 91 and a stamp structure 92 disposed on the glass substrate 91, and the stamp structure 92 includes a base substrate 921 and protrusions 922 located on one side of the base substrate 921 and having a one-piece structure with the base substrate 921. It is a future product trend that the driving substrate has a large size, however the PDMS stamp can only achieve transfer for a driving substrate with a size of 4 inches at present. When a size of the PDMS stamp is increased, the uniformity of a height (i.e., a thickness) of the stamp structure 92 is decreased, which results in a reduced yield of transfer and bonding.

Referring to FIG. 1d which is a schematic diagram illustrating an application of a PDMS stamp in large-size multiple mass transfers, and FIG. 1e which is a schematic diagram illustrating an application of a PDMS stamp in transferring of a small-size array. As shown in FIG. 1d, the micro LED devices on the transfer substrate are transferred to the large-size driving substrate by the PDMS stamp through multiple times of mass (or massive) transfer. As shown in FIG. 1e, the PDMS stamp transfers the micro LED devices, which are arranged in an array in a small-size partial region of the transfer substrate, to the small-size driving substrate.

At present, the mass transfer technology by using the PDMS stamp is more suitable for transferring a micro LED device array on the small-size driving substrate 8, but has the following problems in a mass transfer application of the micro LED devices on the large-size driving substrate 8. For the mass transfer application of the micro LED devices on the large-size driving substrate 8, the increase of an area of the driving substrate 8 means that a larger number of micro LED devices are subjected to the process of transfer and bonding, and a transfer speed, a transfer yield, and a transfer cost of the micro LED devices are the key factors of the process of transfer and bonding.

On one hand, the stamp structure of the PDMS stamp 9 is made of a special material (i.e., a material capable of realizing fast pickup and slow release of the micro LED devices) by injection molding, the manufacturing process thereof is complex and the manufacturing cost is high, and thus is not suitable for mass production and mass transfer to the large-size driving substrate 8.

On the other hand, a method of mass bonding the micro LED devices and the driving substrate 8 together is metal eutectic bonding, which is carried out under a high temperature and a high pressure, for example, the high temperature is usually 180° C. to 300° C. As such, \textcircled{1} during a bonding process, the high temperature and the high pressure will cause the expansion and deformation of the stamp structure of the PDMS stamp 9, such that a transfer precision of the micro LED devices is reduced, and the larger size of the stamp structure of the PDMS stamp 9 will cause the larger reduction in the transfer precision, which limits a size of the PDMS stamp 9 to be small, and a transfer efficiency of the small-size PDMS stamp 9 for mass transferring the micro LED devices to the large-size driving substrate 8 is greatly reduced; \textcircled{2} since the PDMS stamp 9 can only be manufactured to have a small size, multiple times of transfer and bonding are required for the mass transfer to the large-size driving substrate 8, and the repeated presence of the high temperature will cause the aging of the PDMS stamp 9, such that an adhesion force of the PDMS stamp is gradually weakened, and the yield of the PDMS stamp is unstable after performing multiple transfer processes.

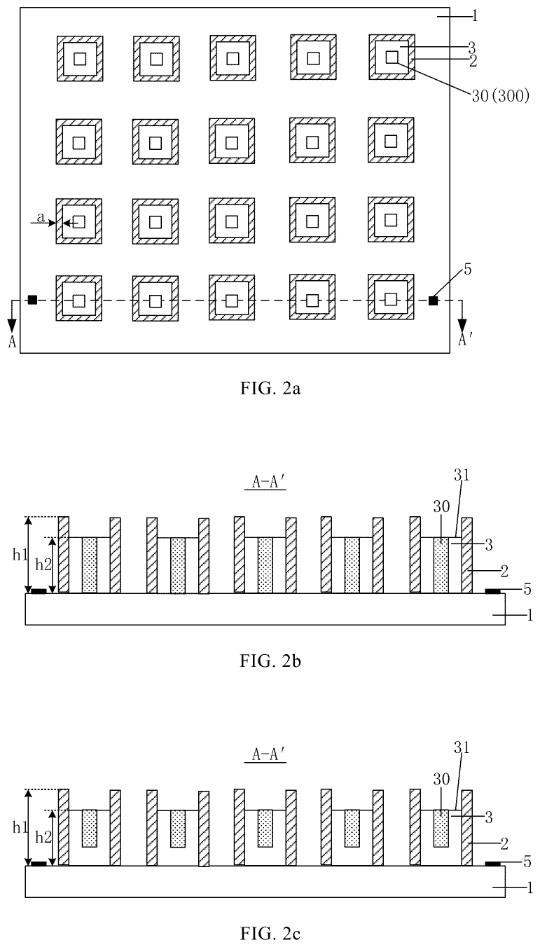

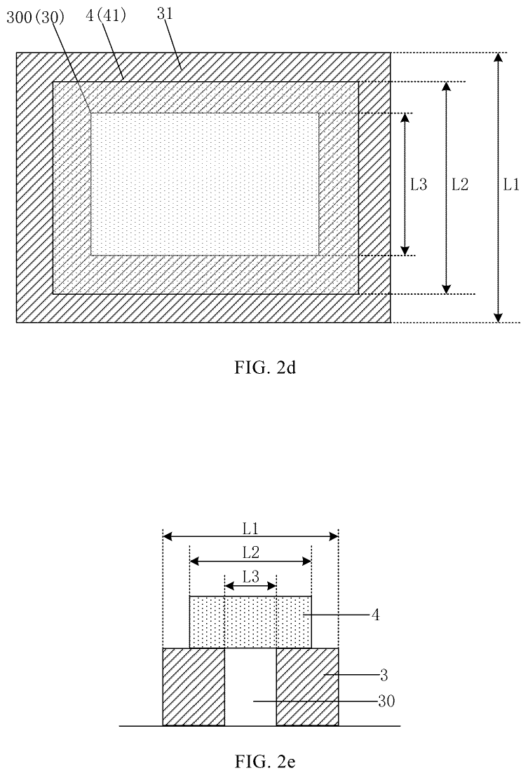

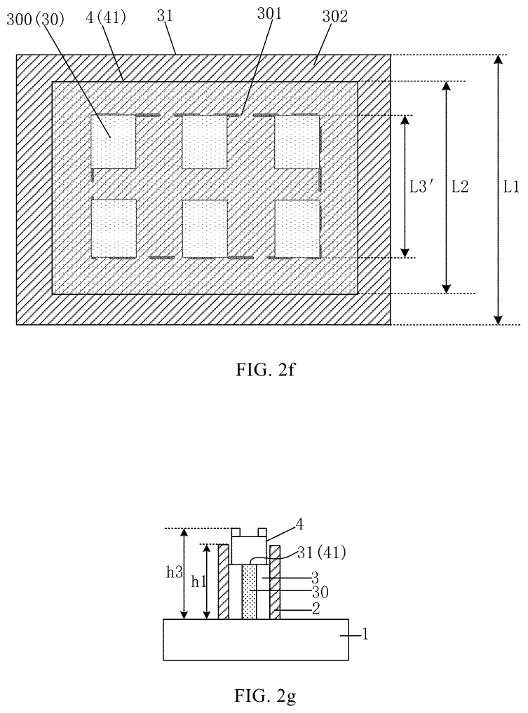

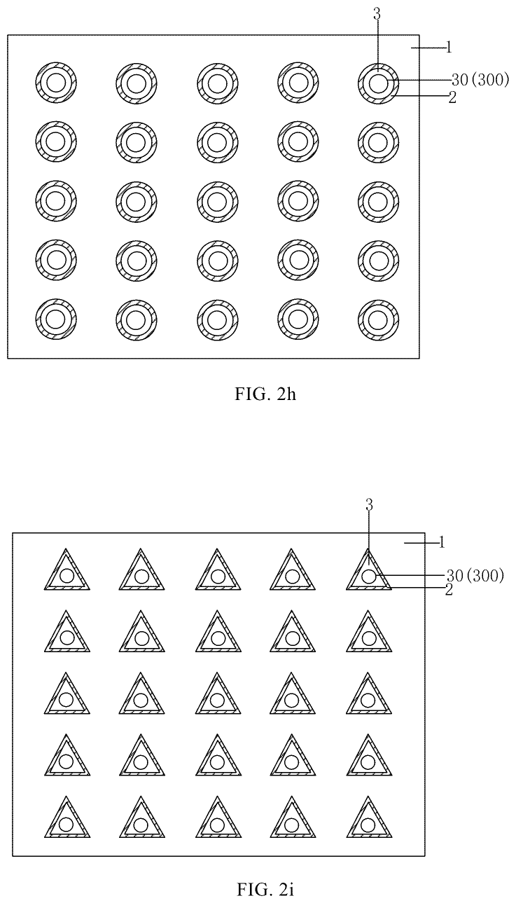

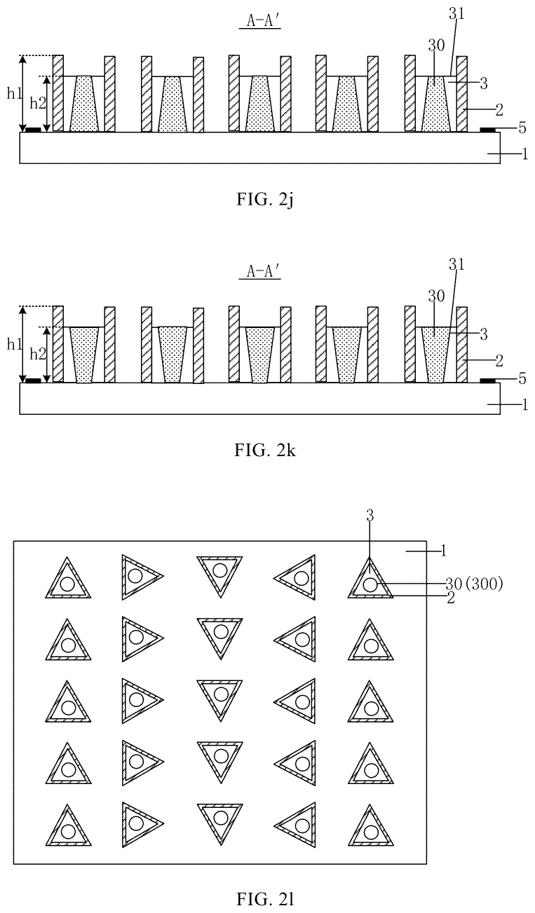

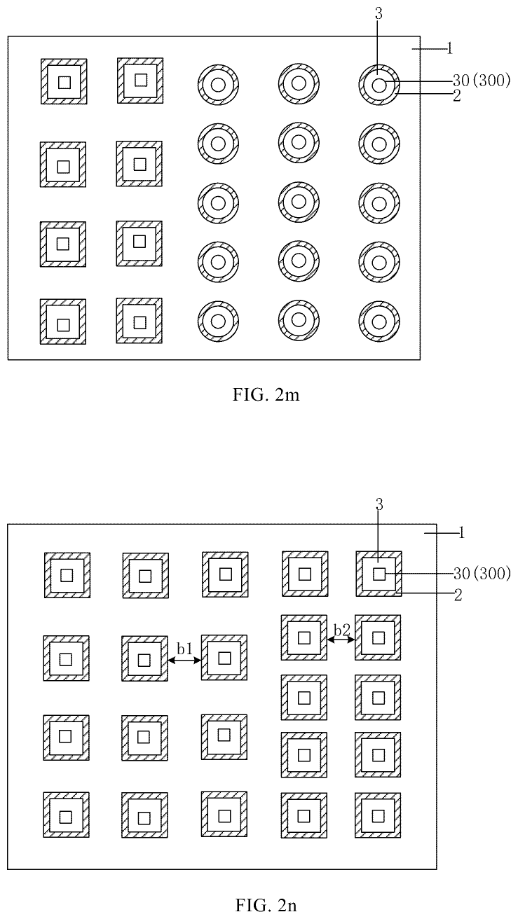

To solve the problems of high cost, low transfer efficiency, and unstable transfer yield of mass transfer realized by using the conventional PDMS stamp, in a first aspect, a stamp is provided by embodiments of the present disclosure. Referring to FIGS. 2a and 2b, where FIG. 2a is a schematic top view illustrating a structure of a stamp according to an embodiment of the present disclosure, and FIG. 2b is a schematic cross-sectional view illustrating a structure of the stamp shown in FIG. 2a taken along a cutting line AA′, the stamp includes: a substrate 1; a plurality of anti-tilting structures 2, which are located on a side of the substrate 1 and are spaced apart from each other; and a plurality of transfer structures 3, which are located on the side of the substrate 1 where the anti-tilting structures 2 are located and are spaced apart from each other. At least one hole 30 is formed in each of the transfer structures 3, and each hole 30 has at least a first opening 300 at a first surface 31 of a corresponding transfer structure 3 distal to the substrate 1. The plurality of anti-tilting structures 2 are in one-to-one correspondence with the plurality of transfer structures 3, the plurality of anti-tilting structures 2 surround peripheries of the respective transfer structures 3, and orthogonal projections of the plurality of anti-tilting structures 2 on the substrate 1 do not overlap with orthogonal projections of the respective transfer structures 3 on the substrate 1. A distance h1 between an end surface, which is distal to the substrate 1, of each anti-tilting structure 2 and the substrate 1 is greater than or equal to a distance h2 between an end surface, which is distal to the substrate 1, of a corresponding transfer structure 3 and the substrate 1.

In some embodiments, the end surface of each transfer structure 3 distal to the substrate 1 is the first surface 31. The stamp can be used for transferring light emitting diodes (such as micro LED devices). The light emitting diodes may be firstly fixed on a transfer substrate, and the plurality of transfer structures 3 transfer the light emitting diodes on the transfer substrate in a one-to-one correspondence manner so as to transfer the light emitting diodes onto a driving substrate. During the process of transferring the light emitting diodes by the stamp, the first surface 31 of each transfer structure 3 distal to the substrate 1 is used for bonding (or attaching) to the light emitting diodes.

By arranging the plurality of transfer structures 3 spaced apart from each other on the substrate 1, heights of the plurality of transfer structures 3 so formed tend to be equal to each other, as compared with a stamp structure of which a base substrate and protrusions have a one-piece structure in the related art, such that the heights of the plurality of transfer structures 3 are better in uniformity, which is beneficial to improving the yield of transfer and bonding of the light emitting diodes transferred by adopting the stamp. Further, by arranging the plurality of anti-tilting structures 2, and the distance h1 between the end surface, which is distal to the substrate 1, of each anti-tilting structure 2 and the substrate 1 being greater than or equal to the distance h2 between the end surface, which is distal to the substrate 1, of the corresponding transfer structure 3 and the substrate 1, on one hand, the anti-tilting structures 2 can limit positions of the respective transfer structures 3, such that the transfer structures 3 will not be tilted and deformed due to a stress difference among parts during a process of eutectic bonding a connecting terminal of a light emitting diode to a connecting terminal of the driving substrate under the high temperature and the high pressure; on the other hand, the anti-tilting structures 2 can limit the positions and transverse expansions (i.e., expansions in a direction parallel to a main surface of the substrate 1) of respective transfer structures 3, such that the transfer structures 3 will not have a transverse displacement relative to the substrate 1 due to thermal expansion during the process of eutectic bonding a connecting terminal of a light emitting diode to a connecting terminal of the driving substrate under the high temperature and the high pressure, thereby avoiding an alignment deviation of the connecting terminal of the light emitting diode from the connecting terminal of the driving substrate during the eutectic bonding process under the high temperature and the high pressure, and improving the yield of transfer and bonding of the light emitting diodes transferred by adopting the stamp. In addition, by forming at least one hole 30 in each transfer structure 3, and making each hole 30 have at least the first opening 300 at the first surface 31 of each transfer structure 3 distal to the substrate 1, each transfer structure 3 can realize adsorption pickup and release separation of the light emitting diodes through different atmospheric pressures formed in the hole 30, thereby improving the efficiency of transferring the light emitting diodes by using the stamp. Meanwhile, based on above-mentioned beneficial effects of the stamp, the stamp according to an embodiment of the present disclosure can be manufactured to have a large size, thereby improving the efficiency of transfer and bonding of the light emitting diodes transferred by using the stamp.

In some embodiments, referring to FIG. 2b, each hole 30 penetrates through a thickness of a corresponding transfer structure 3. That is, each hole 30 is a through hole formed in the corresponding transfer structure 3.

In some embodiments, referring to FIG. 2c which is a schematic cross-sectional view illustrating another structure of the stamp shown in FIG. 2a taken along the cutting line AA′, each hole 30 is a blind hole formed in the corresponding transfer structure 3. That is, each hole 30 penetrates through a part of the thickness of the corresponding transfer structure 3.

In some embodiments, referring to FIG. 2d which is a schematic top view illustrating a dimensional relationship among the first surface of the transfer structure of the stamp according to an embodiment of the present disclosure, the first opening of the transfer structure, and a second surface of a light emitting diode, and FIG. 2e which is a schematic cross-sectional view illustrating a dimensional relationship among the first surface of the transfer structure of the stamp according to an embodiment of the present disclosure, the first opening of the transfer structure, and the second surface of the light emitting diode, the light emitting diode 4 has a second surface 41 in contact with the first surface 31 of the transfer structure 3, and an orthogonal projection of the second surface 41 on the substrate 1 falls within an orthogonal projection of the first surface 31 on the substrate 1. The at least one hole 30 includes one hole. In any direction parallel to the first surface 31, a size L1 of the first surface 31 is greater than a size L2 of the second surface 41, the size L2 of the second surface 41 is greater than a size L3 of the first opening 300, and ½ of a difference between the size L1 of the first surface 31 and the size L3 of the first opening 300 is greater than an alignment accuracy of an alignment device for aligning and attaching the light emitting diode 4 to the transfer structure 3.

In some embodiments, referring to FIG. 2f which is a schematic top view illustrating another dimensional relationship among the first surface of the transfer structure of the stamp according to an embodiment of the present disclosure, the first opening of the transfer structure, and the second surface of the light emitting diode, the first surface 31 of the transfer structure 3 includes a central region 301 and a peripheral region 302 surrounding the central region 301, the at least one hole 30 includes a plurality of holes, and the first openings 300 of the plurality of holes 30 are uniformly distributed in the central region 301.

In some embodiments, with reference to FIG. 2f, the light emitting diode 4 has a second surface 41 in contact with the first surface 31 of the transfer structure 3, and an orthogonal projection of the second surface 41 on the substrate 1 falls within an orthogonal projection of the first surface 31 on the substrate 1. In any direction parallel to the first surface 31, a size L1 of the first surface 31 is greater than a size L2 of the second surface 41, the size L2 of the second surface 41 is greater than a size L3′ of the central region 301, and ½ of a difference between the size L1 of the first surface 31 and the size L3′ of the central region 301 is greater than an alignment accuracy of an alignment device for aligning and attaching the light emitting diode 4 to the transfer structure 3.

Here, a periphery of the central region 301 refers to a line formed by connecting together points, which are farthest from a center of the central region 301, on the outermost edges of the first openings 300 located at the outermost periphery of the central region 301.

By arranging the single hole 30 or the plurality of holes 30 according to an embodiment of the present disclosure, in a process of transferring light emitting diode(s) by the stamp, it can be ensured that the second surface 41 of each light emitting diode 4 covers a corresponding first opening 300 even if the alignment deviation between the transfer structure 3 and any one light emitting diode 4 is the largest, such that a sealed cavity can be formed between each hole 30 and a corresponding light emitting diode 4, thereby ensuring that the light emitting diode(s) 4 can be picked up and released by the transfer structure 3 by setting an air pressure in the hole 30, and finally transferring the light emitting diode(s) 4 by the transfer structure 3.

In some embodiments, referring to FIG. 2g which is a schematic structural cross-sectional view illustrating that the transfer structure of the stamp according to an embodiment of the present disclosure adsorbs (or sticks to) a light emitting diode, the first surface 31 of the transfer structure 3 is configured to contact and attach to the second surface 41 of the light emitting diode 4, and the distance h1 between the end surface of the anti-tilting structure 2 distal to the substrate 1 and the substrate 1 is less than a distance h3 between an end surface of the light emitting diode 4 distal to the substrate 1 and the substrate 1. With such a configuration, the anti-tilting structure 2 can be prevented from being in direct contact with a driving substrate during the process of transferring the light emitting diode 4 by the transfer structure 3, because the anti-tilting structure 2 is configured to limit a position of the transfer structure 3 and prevent the transfer structure 3 from being tilted, and the direct contact of the anti-tilting structure 2 with the driving substrate will have an influence on the alignment and boing of the light emitting diode 4 to the driving substrate.

In some embodiments, referring to FIG. 2a, a shape of the orthogonal projection of each anti-tilting structure 2 on the substrate 1 is a ring, and shapes of the orthogonal projections of the transfer structures 3 on the substrate 1 abut on shapes of the orthogonal projections of the respective anti-tilting structures 2 on the substrate 1. With such a configuration, the anti-tilting structures 2 can effectively limit the positions, tilting (i.e., inclination), and transverse expansions (i.e., expansions in a direction parallel to a main surface of the substrate 1) of the respective transfer structures 3, such that the transfer structures 3 will not be tilted and will not transversely displace relative to the substrate 1 due to thermal expansion during a process of eutectic bonding a connecting terminal of the light emitting diode to a connecting terminal of the driving substrate under a high temperature and a high pressure, thereby avoiding the alignment deviation between the connecting terminal of the light emitting diode and the connecting terminal of the driving substrate during the process of eutectic bonding under the high temperature and the high pressure, and improving a yield of transfer and bonding of the light emitting diodes transferred by using the stamp.

In some embodiments, referring to FIG. 2a, FIG. 2h which is a schematic top view illustrating a structure of another stamp according to an embodiment of the present disclosure, and FIG. 2i which is a schematic top view illustrating a structure of another stamp according to an embodiment of the present disclosure, the shape of the orthogonal projection of each transfer structure 3 on the substrate 1 includes a circle, a rectangle, a triangle, or a polygon.

In some embodiments, referring to FIGS. 2a, 2h and 2i, a shape of the orthogonal projection of each first opening 300 on the substrate 1 includes a circle, a rectangle, a triangle, or a polygon.

In some embodiments, referring to FIGS. 2a and 2h, a shape of the first surface 31 of the transfer structure 3 is similar or identical to a shape of a corresponding first opening 300. Referring to FIG. 2i, the shape of the first surface 31 of each transfer structure 3 is different from the shape of a corresponding first opening 300.

In some embodiments, referring to FIG. 2b, FIG. 2j which is a schematic cross-sectional view illustrating another structure of the stamp shown in FIG. 2a taken along the cutting line AA′, and FIG. 2k which is a schematic cross-sectional view illustrating another structure of the stamp shown in FIG. 2a taken along the cutting line AA′, a shape of a section, which is perpendicular to the substrate 1, of each hole 30 includes a rectangle (as shown in FIG. 2b), a trapezoid (as shown in FIG. 2j), or an inverted trapezoid (as shown in FIG. 2k).

In some embodiments, referring to FIGS. 2a, 2h and 2i, the plurality of transfer structures 3 are arranged to be equally spaced apart from each other in an array. Referring to FIG. 2l which is a schematic top view illustrating a structure of another stamp according to an embodiment of the present disclosure, the shapes of the orthogonal projections of the plurality of transfer structures 3 on the substrate 1 are identical to each other, but the shapes of the orthogonal projections of any two adjacent columns of transfer structures 3 on the substrate 1 have different orientations (i.e., are oriented in different directions). As shown in FIG. 2l, the shapes of the orthogonal projections of the plurality of transfer structures 3 on the substrate 1 are all triangles, but the triangles of the orthogonal projections of any two adjacent columns of transfer structures 3 on the substrate 1 have different orientations. Referring to FIG. 2m which is a schematic top view illustrating a structure of another stamp according to an embodiment of the present disclosure, the shapes of the orthogonal projections of some of the plurality of transfer structures 3 on the substrate 1 are different from the shapes of the orthogonal projections of others of the plurality of transfer structures 3 on the substrate 1. As shown in FIG. 2m, the shapes of the orthogonal projections of some of the plurality of transfer structures 3 on the substrate 1 are rectangles, whereas the shapes of the orthogonal projections of others of the plurality of transfer structures 3 on the substrate 1 are circles.

In some embodiments, referring to FIG. 2n which is a schematic top view illustrating a structure of another stamp according to an embodiment of the present disclosure, some of the plurality of transfer structures 3 are arranged in an array to be spaced apart from each other by a first distance b1, and others of the plurality of transfer structures 3 are arranged in an array to be spaced apart from each other by a second distance b2, where the first distance b1 is greater than the second distance b2.

In some embodiments, each transfer structure 3 is made of an elastic resin material, which includes any one of polymethyl methacrylate, propylene glycol methyl ether acetate, silicon resin, or acrylic resin. Since each transfer structure 3 is made of the elastic material, any surface unevenness generated in the processes of transferring and bonding of the light emitting diodes can be compensated, and the transfer yield of the light emitting diodes is improved. In the present embodiment, the material of each transfer structure 3 is not required to have a high light transmittance and a high viscosity.

In some embodiments, a material of each anti-tilting structure 2 includes any one of silicon oxide, silicon nitride, silicon oxynitride, copper, aluminum, molybdenum, or silver.

In some embodiments, each transfer structure 3 has a height in a range of 4 μm to 15 μm. Here, the height of a transfer structure 3 is a thickness of the transfer structure 3 in the direction away from the substrate 1. By setting such a height range, on one hand, the uniformity of the heights of the plurality of transfer structures 3 on the substrate 1 can be effectively improved, and on the other hand, the transfer structures 3 can effectively transfer the light emitting diodes, thereby improving the transfer yield.

In some embodiments, a linewidth a of the ring of each anti-tilting structure 2 is in a range of 2 μm to 30 μm. By setting such a range for the linewidth a of the ring, it can be ensured that the anti-tilting structures 2 stably limits the positions and transverse expansions (i.e., expansions in the direction parallel to the main surface of the substrate 1) of the respective transfer structures 3.

In some embodiments, referring to FIGS. 2a and 2b, the stamp further includes a plurality of alignment marks 5 located on the side of the substrate 1 where the anti-tilting structures 2 are located, and located in a peripheral region or a central region of the substrate 1. Further, orthogonal projections of the alignment marks 5 on the substrate 1 do not overlap with the orthogonal projections of the anti-tilting structures 2 and the transfer structures 3 on the substrate 1.

The alignment marks 5 are configured to align the transfer structures 3 with the light emitting diodes when the stamp picks up the light emitting diodes from the transfer substrate, and align the connecting terminals of the light emitting diodes with the connecting terminals of the driving substrate when the stamp transfers the light emitting diodes to the driving substrate.

In some embodiments, each alignment mark 5 is made of a metal material, such as molybdenum, titanium, aluminum, silver, and/or the like. In some embodiments, a shape of the orthogonal projection of each alignment mark 5 on the substrate 1 includes a rectangle, a circle, a cross, or the like. A size of each alignment mark 5 may be determined according to the recognition accuracy of the alignment device, and is not particularly limited herein.

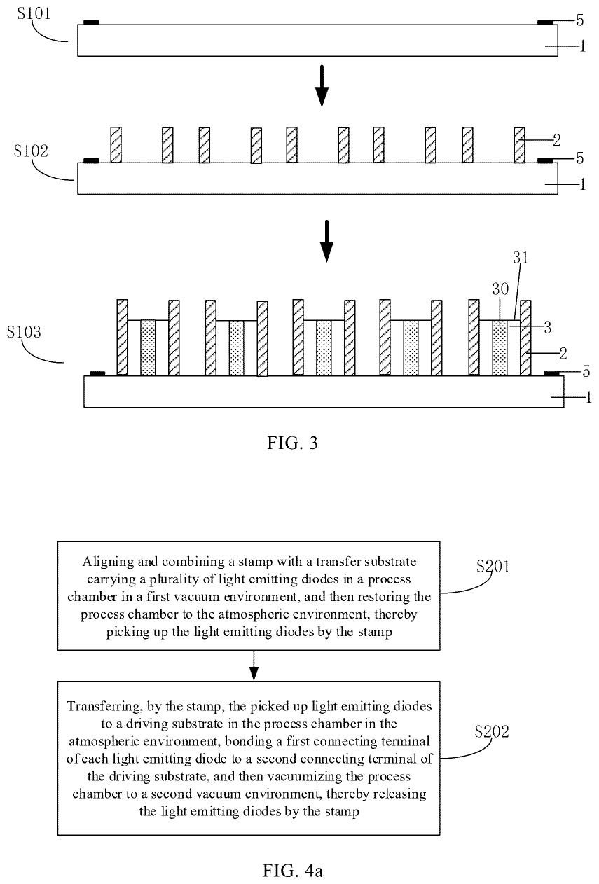

In a second aspect, based on the above structures of the stamp, an embodiment of the present disclosure further provides a method for manufacturing the stamp. Referring to FIG. 3 which is a flowchart of a method for manufacturing the stamp according to an embodiment of the present disclosure, the method includes the following steps S102 and S103. Step S102 includes forming a plurality of anti-tilting structures 2 on a side of the substrate 1 by a patterning process.

Step S103 includes forming a plurality of transfer structures 3 on the side of the substrate 1 where the above step is completed by a patterning process. The plurality of transfer structures 3 and the plurality of anti-tilting structures 2 are located on the same side of the substrate 1.

The forming a plurality of transfer structures 3 includes simultaneously forming a pattern of the transfer structures 3 and a pattern of hole(s) 30 in each of the transfer structures 3.

In the present embodiment, the method further includes, prior to step S102, step S101 of forming a plurality of alignment marks 5 on the side of the substrate 1 by a patterning process. The patterning process for forming the alignment marks 5 includes steps of depositing to form a film, photoresist coating, exposure, development, etching, and the like, which will not be repeated hereinafter.

The method for manufacturing the stamp according to the present embodiment is realized through traditional patterning processes, and thus is simple, has a high manufacturing precision and a low manufacturing cost, and can manufacture a large-size stamp. The manufactured stamp can not only improve the yield of transfer and bonding of the light emitting diodes, but also improve an efficiency of transfer and bonding of the light emitting diodes.

In some embodiments, step S102 of forming a plurality of anti-tilting structures 2 on a side of the substrate 1 by a patterning process includes the following steps S1021 to S1026. Step S1021 includes depositing an anti-tilting structure film on the side of the substrate.

In the present step, the anti-tilting structure film may be made of an inorganic insulating material such as silicon nitride, silicon oxide or silicon oxynitride, and in this case, the anti-tilting structure film is formed through chemical vapor deposition. Alternatively, the anti-tilting structure film may be made of a metal material such as copper, aluminum, molybdenum, or silver, and in this case, the anti-tilting structure film is formed by sputtering deposition.

Step S1022 includes coating a photoresist layer on a side of the anti-tilting structure film distal to the substrate.

Step S1023 includes exposing the photoresist layer by using a mask including a pattern of the anti-tilting structures.

Step S1024 includes developing to remove the photoresist in exposed regions of the photoresist layer.

In the present step, portions of the photoresist layer in regions outside the pattern of the anti-tilting structures are developed and removed.

Step S1025 includes etching and removing portions of the anti-tilting structure film which are not covered by the photoresist by a dry etching process or a wet etching process to form the pattern of the plurality of anti-tilting structures.

In the present step, the anti-tilting structure film made of the inorganic insulating material is removed by the dry etching process, and the anti-tilting structure film made of the metal material is removed by the wet etching process.

Step S1026 includes stripping off the residual photoresist.

In some embodiments, step S103 of forming a plurality of transfer structures 3 on the side of the substrate 1 where the above step is completed by a patterning process includes: coating a layer of organic resin material on the side of the substrate.

Step S103 further includes exposing the layer of organic resin material by using a mask including a pattern of the transfer structures.

Step S103 further includes developing to remove the organic resin material in exposed regions of the layer of organic resin material to form the pattern of the plurality of transfer structures.

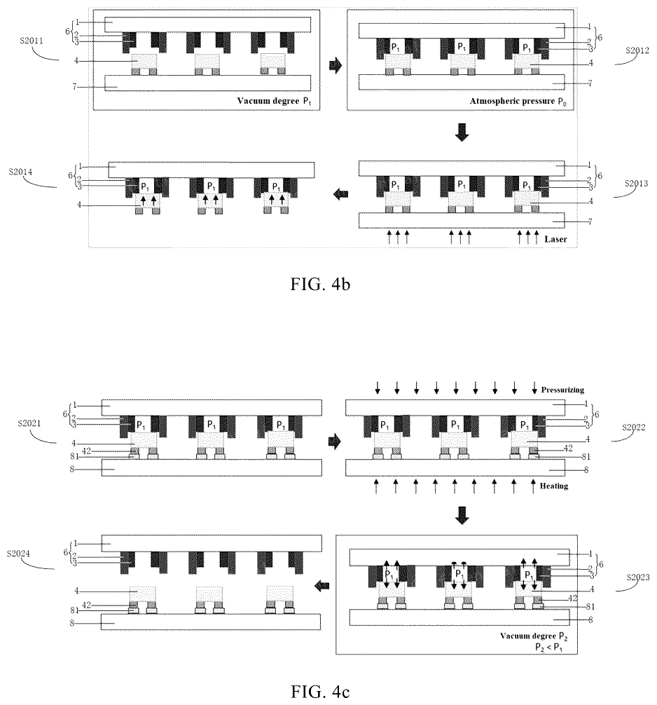

In a third aspect, an embodiment of the present disclosure further provides a mass transfer method, and referring to FIG. 4a which is a flowchart of a mass transfer method according to an embodiment of the present disclosure, FIG. 4b which is a schematic diagram illustrating a process of picking up light emitting diodes from a transfer substrate by a stamp according to an embodiment of the present disclosure, and FIG. 4c which is a schematic diagram illustrating a process of transferring and releasing light emitting diodes to a driving substrate by a stamp according to an embodiment of the present disclosure, the mass transfer method includes the following steps S201 and S202. Step S201 includes aligning and combining a stamp 6 with a transfer substrate 7 carrying a plurality of light emitting diodes 4 in a process chamber in a first vacuum environment, and then restoring the process chamber to the atmospheric environment, thereby picking up the light emitting diodes 4 by the stamp 6.

In the present step, an air pressure in the first vacuum environment is less than an air pressure in the atmospheric environment, a plurality of transfer structures 3 of the stamp 6 are in one-to-one correspondence with at least some of the light emitting diodes 4, and the second surfaces of the light emitting diodes 4 cover the first openings at the first surfaces of the respective transfer structures 3, such that the holes in the transfer structures 3 form sealed cavities.

Step S202 includes transferring, by the stamp 6, the picked up light emitting diodes 4 to a driving substrate 8 in the process chamber in the atmospheric environment, bonding a first connecting terminal 42 of each light emitting diode 4 to a second connecting terminal 81 of the driving substrate 8, and then vacuumizing the process chamber to a second vacuum environment, thereby releasing the light emitting diodes 4 by the stamp.

In the present step, an air pressure in the second vacuum environment is less than the air pressure in the first vacuum environment.

In the mass transfer method, during the process of picking up the light emitting diodes 4, the process chamber is switched from the first vacuum environment to the atmospheric environment, such that positive pressures are formed in sealed cavities formed between the stamp 6 and the light emitting diodes 4, and the light emitting diodes 4 are picked up; during the process of releasing the light emitting diodes, the process chamber is switched from the atmospheric environment to the second vacuum environment, such that negative pressures are formed in sealed cavities formed between the stamp 6 and the light emitting diodes 4, and the light emitting diodes 4 are released, thereby achieving mass transfer and boding of the light emitting diodes. As compared with a stamp of which a transfer structure needs to be additionally provided with a vent mechanism having a vent hole in the related art, the mass transfer method according to the present embodiment does not need to add a vent mechanism having a vent hole on each transfer structure of the stamp, but changes a vacuum degree of the process chamber during the process of transferring the light emitting diodes 4 so as to form positive pressures or negative pressures in sealed cavities formed between the stamp 6 and the light emitting diodes 4, so that the whole process of the mass transfer method according to the present embodiment is simpler.

In some embodiments, referring to FIG. 4b, step S201 of aligning and combining a stamp 6 with a transfer substrate 7 carrying a plurality of light emitting diodes 4 in a process chamber in a first vacuum environment, and then restoring the process chamber to the atmospheric environment, thereby picking up the light emitting diodes 4 by the stamp 6 includes the following steps S2011 to S2014. Step S2011 includes aligning and pressing the stamp 6 and the transfer substrate 7 together in the process chamber in the first vacuum environment.

In the present step, the stamp 6 and the transfer substrate 7 carrying the light emitting diodes 4 are aligned and pressed together in the first vacuum environment. Since each transfer structure of the stamp 6 has a high elasticity, it can be ensured that the transfer structures of the stamp 6 are completely attached to all the light emitting diodes to be picked up, a sealed cavity is formed between the hole in each transfer structure and a corresponding light emitting diode 4, and the vacuum degree in the sealed cavity is P1, i.e., the air pressure in the sealed cavity is P1.

Step S2012 includes restoring the process chamber to the atmospheric environment to form a negative pressure in each sealed cavity.

In the present step, after the stamp 6 and the transfer substrate 7 are attached to each other, the pressure inside the process chamber is restored to the atmospheric pressure P0. Since P1<P0, a large negative pressure is formed in each sealed cavity between the stamp 6 and each light emitting diode 4, the attaching interface between the stamp 6 and each light emitting diode 4 is in a strong adhesion state, and the light emitting diodes are successfully picked up onto the stamp 6.

Step S2013 includes dissociating an adhesive layer for fixing the light emitting diodes 4 on the transfer substrate 7 by means of laser dissociation.

In the present step, laser scanning irradiation may be performed, by laser scanning, on the adhesive layer which is located between the transfer substrate 7 and the light emitting diodes 4 for fixedly adhering them together, to achieve dissociation of the adhesive layer. Alternatively, the adhesive layer which is located between the transfer substrate 7 and the light emitting diodes 4 for fixedly adhering them together may be irradiated by laser (i.e., laser light) point by point to achieve dissociation of the adhesive layer.

Step S2014 includes separating the dissociated transfer substrate 7 from the stamp 6, thereby transferring the light emitting diodes 4 to the stamp 6.

In some embodiments, referring to FIG. 4c, step S202 of transferring, by the stamp 6, the picked up light emitting diodes 4 to a driving substrate 8 in the process chamber in the atmospheric environment, bonding a first connecting terminal 42 of each light emitting diode 4 to a second connecting terminal 81 of the driving substrate 8, and then vacuumizing the process chamber to a second vacuum environment, thereby releasing the light emitting diodes 4 by the stamp includes the following steps S2021 to S2024. Step S2021 includes aligning and attaching the stamp 6 carrying the light emitting diodes 4 to the driving substrate 8 in the process chamber in the atmospheric environment, to bond the first connecting terminal 42 of each light emitting diode 4 to a corresponding second connecting terminal 81 of the driving substrate 8.

Step S2022 includes applying a pressure to the stamp 6, and heating the driving substrate 8, to complete bonding of the first connecting terminal 42 to the corresponding second connecting terminal 81.

In the present step, the pressure applied to the stamp 6 is a pressure listed in the following Table 1, and a temperature to which the driving substrate 8 is heated is a temperature listed in Table 1. Eutectic bonding of the first connecting terminal 42 to the corresponding second connecting terminal 81 is completed under the process conditions of pressurizing and heating as listed in Table 1.

TABLE 1

| Bonding | Bonding type | | | | | | | |
|---|---|---|---|---|---|---|---|---|
| condition | Cu—Sn | | Cu—In | | Au—Sn | | Au—In | |
| Cleaning | Organic | | 10% dilute | | Organic | | 10% dilute | |
| | weak acid | | HCl cleaning | | weak acid | | HCl cleaning | |
| | solution or | | | | solution or | | | |
| | vapor | | | | vapor | | | |
| Atmosphere | Inert or | | Inert or | | Inert or | | Inert or | |
| | vacuum | | vacuum | | vacuum | | vacuum | |
| Reference | 250° C. to | | 200° C. to | | 240° C. to | | 180° C. to | |
| temperature | 300° C. | | 280° C. | | 300° C. | | 200° C. | |
| Reference | 1 | MPa | 0.5 | MPa | 1 | MPa | 2 | MPa |
| pressure | | | | | | | | |
| Reference | <30 | min | <30 | min | <30 | min | <30 | min |
| time | | | | | | | | |
| Bonding | 40 | MPa | 11 | MPa | 140 | MPa | 30 | MPa |
| strength (in | | | | | | | | |
| theory) | | | | | | | | |

In some embodiments, the applying a pressure to the stamp 6 includes mechanically pressurizing or gaseously pressurizing. Here, the gaseously pressurizing is adjusting the pressure of air in the process chamber to meet the requirements as listed in Table 1.

In some embodiments, there are two first connecting terminals 42 and two second connecting terminals 81, and the two first connecting terminals 42 are connected in one-to-one correspondence with the two second connecting terminals 81.

Step S2023 includes vacuumizing the process chamber to the second vacuum environment to form a positive pressure in each sealed cavity.

In the present step, after the bonding of the light emitting diodes 4 to the driving substrate 8 is completed, the process chamber is vacuumized to adjust the vacuum degree in the process chamber to P2, i.e., to adjust the pressure of air in the process chamber to P2, and P2<P1. That is, a positive pressure is realized in the sealed cavity between the stamp 6 and each light emitting diode 4, thereby releasing each light emitting diode 4 by the stamp 6.

Step S2024 includes separating the stamp 6 from each light emitting diode 4 to transfer the light emitting diode 4 to the driving substrate 8.

In the mass transfer method according to the present embodiment, by adopting the stamp according to any one of the foregoing embodiments, the plurality of light emitting diodes on the transfer substrate can not only be transferred in batches multiple times, but also be all transferred one time, such that the yield of transfer and bonding of the light emitting diodes is improved, and the efficiency of transfer and bonding of the light emitting diodes is improved.

In a fourth aspect, an embodiment of the present disclosure further provides a transfer device, which includes the stamp according to any one of the foregoing embodiments.

The transfer device can transfer huge amounts of light emitting diodes (i.e., LEDs), micro light emitting diodes (i.e., micro LEDs), and mini light emitting diodes (i.e., mini LEDs).

By including the stamp according to any one of the foregoing embodiments, the transfer device can realize one-time transfer of the plurality of light emitting diodes on the transfer substrate, and thus has an improved yield of transfer and bonding and an improved efficiency of transfer and bonding.

It will be understood that the foregoing embodiments are merely exemplary embodiments adopted to illustrate the principles of the present disclosure, and the present disclosure is not limited thereto. It will be apparent to one of ordinary skill in the art that various changes and modifications may be made therein without departing from the spirit and scope of the present disclosure, and such changes and modifications are to be considered within the scope of the present disclosure.

1. A stamp, comprising
a substrate;
a plurality of anti-tilting structures, which are located on a side of the substrate and are spaced apart from each other; and
a plurality of transfer structures, which are located on the side of the substrate where the anti-tilting structures are located and are spaced apart from each other, wherein
each transfer structure has therein at least one hole, and each hole has at least a first opening at a first surface, which is distal to the substrate, of a corresponding transfer structure;
the plurality of anti-tilting structures are in one-to-one correspondence with the plurality of transfer structures;
the plurality of anti-tilting structures surround peripheries of the respective transfer structures, and orthogonal projections of the plurality of anti-tilting structures on the substrate do not overlap with orthogonal projections of the respective transfer structures on the substrate; and
a distance between an end surface, which is distal to the substrate, of each anti-tilting structure and the substrate is greater than or equal to a distance between an end surface, which is distal to the substrate, of a corresponding transfer structure and the substrate.

2. The stamp according to claim 1, wherein each hole penetrates through a thickness of a corresponding transfer structure.

3. The stamp according to claim 1, wherein each hole is a blind hole formed in a corresponding transfer structure.

4. The stamp according to claim 2, wherein a light emitting diode has a second surface in contact with the first surface of a corresponding transfer structure, and an orthogonal projection of the second surface on the substrate falls within an orthogonal projection of the first surface on the substrate;
the at least one hole comprises one hole;
in any direction parallel to the first surface, a size of the first surface is greater than a size of the second surface, and the size of the second surface is greater than a size of the first opening; and
½ of a difference between the size of the first surface and the size of the first opening is greater than an alignment accuracy of an alignment device for aligning and attaching the light emitting diode to the corresponding transfer structure.

5. The stamp according to claim 2, wherein the first surface of the transfer structure comprises a central region and a peripheral region surrounding the central region; and
the at least one hole comprises a plurality of holes, and first openings of the plurality of holes are uniformly distributed in the central region.

6. The stamp according to claim 5, wherein a light emitting diode has a second surface in contact with the first surface of the corresponding transfer structure, and an orthogonal projection of the second surface on the substrate falls within an orthogonal projection of the first surface on the substrate;
in any direction parallel to the first surface, a size of the first surface is greater than a size of the second surface, and the size of the second surface is greater than a size of the central region; and
½ of a difference between the size of the first surface and the size of the central region is greater than an alignment accuracy of an alignment device for aligning and attaching the light emitting diode to the corresponding transfer structure.

7. The stamp according to claim 1, wherein the first surface of each transfer structure is configured to contact and attach to a second surface of a light emitting diode, and a distance between an end surface of each anti-tilting structure distal to the substrate and the substrate is less than a distance between an end surface of the light emitting diode distal to the substrate and the substrate.

8. The stamp according to claim 1, wherein a shape of the orthogonal projection of each anti-tilting structure on the substrate is a ring; and
shapes of the orthogonal projections of the transfer structures on the substrate abut on shapes of the orthogonal projections of the respective anti-tilting structures on the substrate.

9. The stamp according to claim 8, wherein the shape of the orthogonal projection of each transfer structure on the substrate comprises a circle, a rectangle, a triangle, or a polygon.

10. The stamp according to claim 9, wherein a shape of an orthogonal projection of each first opening on the substrate comprises a circle, a rectangle, a triangle, or a polygon; or
wherein a shape of a section, which is perpendicular to the substrate, of each hole comprises a rectangle, a trapezoid, or an inverted trapezoid; or
wherein the plurality of transfer structures are arranged to be equally spaced apart from each other in an array; and the shapes of the orthogonal projections of the plurality of transfer structures on the substrate are identical to each other, and the shapes of the orthogonal projections of any two adjacent columns of transfer structures on the substrate have different orientations; or, the shapes of the orthogonal projections of some of the plurality of transfer structures on the substrate are different from the shapes of the orthogonal projections of the plurality of transfer structures on the substrate; or
wherein some of the plurality of transfer structures are arranged in an array to be spaced apart from each other by a first distance, and others of the plurality of transfer structures are arranged in an array to be spaced apart from each other by a second distance, where the first distance is greater than the second distance.

11-13. (canceled)

14. The stamp according to claim 1, wherein
each transfer structure is made of an elastic resin material, and the elastic resin material comprises any one of polymethyl methacrylate, propylene glycol methyl ether acetate, silicon resin, or acrylic resin; or
wherein a material of each anti-tilting structure comprises any one of silicon oxide, silicon nitride, silicon oxynitride, copper, aluminum, molybdenum, or silver; or
wherein each transfer structure has a height in a range of 4 μm to 15 μm.

15-16. (canceled)

17. The stamp according to claim 8, wherein a linewidth of the ring of each anti-tilting structure is in a range of 2 μm to 30 μm.

18. A transfer device, comprising the stamp according to claim 1.

19. A method for manufacturing a stamp, the method comprising:
forming a plurality of anti-tilting structures on a side of a substrate by a patterning process; and
forming a plurality of transfer structures on the side of the substrate where the above step is completed by a patterning process, to form the plurality of transfer structures and the plurality of anti-tilting structures on the same side of the substrate;
wherein the forming a plurality of transfer structures comprises simultaneously forming a pattern of the transfer structures and a pattern of a hole in each of the transfer structures.

20. The method according to claim 19, wherein the forming a plurality of anti-tilting structures on a side of a substrate by a patterning process comprises:
depositing an anti-tilting structure film on the side of the substrate;
coating a photoresist layer on a side of the anti-tilting structure film distal to the substrate;
exposing the photoresist layer by using a mask including a pattern of the anti-tilting structures;
developing to remove photoresist in exposed regions of the photoresist layer;
etching and removing portions of the anti-tilting structure film which are not covered by the photoresist by a dry etching process or a wet etching process to form the pattern of the plurality of anti-tilting structures; and
stripping off residual photoresist.

21. The method according to claim 19, wherein the forming a plurality of transfer structures on the side of the substrate where the above step is completed by a patterning process comprises:
coating a layer of organic resin material on the side of the substrate;
exposing the layer of organic resin material by using a mask including a pattern of the transfer structures; and
developing to remove the organic resin material in exposed regions of the layer of organic resin material to form the pattern of the plurality of transfer structures.

22. A mass transfer method, comprising:
aligning and combining a stamp with a transfer substrate carrying a plurality of light emitting diodes in a process chamber in a first vacuum environment, and then restoring the process chamber to the atmospheric environment, thereby picking up the light emitting diodes by the stamp, wherein an air pressure in the first vacuum environment is less than an air pressure in the atmospheric environment, a plurality of transfer structures of the stamp are in one-to-one correspondence with at least some of the plurality of light emitting diodes, and second surfaces of the light emitting diodes cover first openings at first surfaces of respective transfer structures, such that holes in the transfer structures form sealed cavities; and
transferring, by the stamp, the picked up light emitting diodes to a driving substrate in the process chamber in the atmospheric environment, bonding a first connecting terminal of each light emitting diode to a second connecting terminal of the driving substrate, and then vacuumizing the process chamber to a second vacuum environment, thereby releasing the light emitting diodes by the stamp, wherein an air pressure in the second vacuum environment is less than the air pressure in the first vacuum environment.

23. The mass transfer method according to claim 22, wherein the aligning and combining a stamp with a transfer substrate carrying a plurality of light emitting diodes in a process chamber in a first vacuum environment, and then restoring the process chamber to the atmospheric environment, thereby picking up the light emitting diodes by the stamp comprise:
aligning and pressing the stamp and the transfer substrate together in the process chamber in the first vacuum environment;
restoring the process chamber to the atmospheric environment to form a negative pressure in each sealed cavity;
dissociating an adhesive layer for fixing the light emitting diodes on the transfer substrate by means of laser dissociation; and
separating dissociated transfer substrate from the stamp, thereby transferring the light emitting diodes to the stamp.

24. The mass transfer method according to claim 22, wherein the transferring, by the stamp, the picked up light emitting diodes to a driving substrate in the process chamber in the atmospheric environment, bonding a first connecting terminal of each light emitting diode to a second connecting terminal of the driving substrate, and then vacuumizing the process chamber to a second vacuum environment, thereby releasing the light emitting diodes by the stamp comprise:
aligning and attaching the stamp carrying the light emitting diodes to the driving substrate in the process chamber in the atmospheric environment, to bond the first connecting terminal of each light emitting diode to a corresponding second connecting terminal of the driving substrate;
applying a pressure to the stamp, and heating the driving substrate, to complete bonding of the first connecting terminal to the corresponding second connecting terminal;
vacuumizing the process chamber to the second vacuum environment to form a positive pressure in each sealed cavity; and
separating the stamp from the light emitting diodes to transfer the light emitting diodes to the driving substrate.

25. The mass transfer method according to claim 24, wherein the applying a pressure to the stamp comprises:
mechanically pressurizing; or
gaseously pressurizing.
